(19) United States
(12) Patent Application Publication
(10) Pub. No.: US 2005/0275056 A1
(43) Pub. Date: Dec. 15, 2005

(54) Organic heterojunction bipolar transistor

(76) Inventor: Stephen Forrest, Princeton, NJ (US)

Correspondence Address: THOMAS F. MEAGHER;KENYON & KENYON, ONE BROADWAY, NEW YORK, NY, 10004, US

(21) Appl. No.: 10/853,188

(22) Filed: May 26, 2004

(51) Int. Cl. H01L 27/095

(52) U.S. Cl. 257/479; 257/499

(57) ABSTRACT

A transistor is disclosed comprising a collector, which itself comprises a small molecule organic material. A base comprising a doped small molecule organic material that forms a junction with the collector and an emitter comprising a small molecule organic material that forms a junction with the base is further disclosed. Electrodes are coupled to the collector, base and emitter. The transistor is bipolar.

### FIELD OF THE INVENTION

The present invention relates to organic transistors, and more specifically to organic heterojunction bipolar transistors.

### BACKGROUND

Opto-electronic devices that make use of organic materials are becoming increasingly desirable for a number of reasons. Many of the materials used to make such devices are relatively inexpensive, so organic opto-electronic devices have the potential for cost advantages over inorganic devices. In addition, the inherent properties of organic materials, such as their flexibility, may make them well suited for particular applications such as fabrication on a flexible substrate. Examples of organic opto-electronic devices include organic light emitting devices (OLEDs), organic transistors/phototransistors, organic photovoltaic cells, and organic photodetectors. For OLEDs, the organic materials may have performance advantages over conventional (i.e., inorganic) materials. For example, the wavelength at which an organic emissive layer emits light may generally be readily tuned with appropriate dopants. For organic transistors/phototransistors, the substrates upon which they are constructed may be flexible, providing for broader applications in industry and commerce.

Most reported research and development on organic transistors has been conducted using a class of transistors known as field effect transistors (FETs). Typical organic field effect transistors are fabricated using a lateral architecture. See, e.g., Shtein et al., “Effects of film morphology and gate dielectric surface preparation on the electrical characteristics of organic vapor phase deposited Pentacene thin-film transistors,” Appl. Phys. Lett., vol. 8 1, pp. 268, 2002; Gundlach et al., “Pentacene organic thin film transistors-molecular ordering and mobility,” IEEE Electron. Dev. Lett., vol. 18, pp. 87, 1997; Lin et al., “Pentacene Thin Film Transistors with Improved Subthreshold Slope,” presented at Mat. Res. Soc. Spring Mtg., San Francisco, Calif., 1997; and Lin et al., “High-mobility pentacene-based organic thin film transistors,” presented at 55th Ann. Dev. Res. Conf., Ft. Collins, Colo., 1997.

One researcher provides information on a field effect transistor constructed in a “V” shaped channel. See N. Stutzmann et al., “Self-aligned, vertical-channel, polymer field-effect transistors,” Science, vol. 299, pp. 1881, 2003.

In known field effect transistor configurations, the active organic semiconductor may be deposited to a thickness of ˜100 nm onto an oxide or other insulating layer covering the gate contact, typically ˜10 μm long. The source and drain contacts are then deposited, often through shadow masks that ultimately limit the gate dimensions to several microns, onto the surfaces of the organic source region and drain region. Hence, the transit distance from source to drain may be on the order of several microns as well.

As used herein, the term “organic” includes polymeric materials as well as small molecule organic materials that may be used to fabricate organic devices including opto-electronic devices. “Small molecule” refers to any organic material that is not a polymer, and “small molecules” may actually be quite large. Small molecules may include repeat units in some circumstances. For example, using a long chain alkyl group as a substituent does not remove a molecule from the “small molecule” class. Small molecules may also be incorporated into polymers, for example as a pendent group on a polymer backbone or as a part of the backbone. Small molecules may also serve as the core moiety of a dendrimer, which consists of a series of chemical shells built on the core moiety. The core moiety of a dendrimer may be a fluorescent or phosphorescent small molecule emitter. A dendrimer may be a “small molecule,” and it is believed that all dendrimers currently used in the field of OLEDs are small molecules.

### SUMMARY OF THE INVENTION

A transistor is disclosed that comprises a collector, which itself is comprised of a small molecule organic material. A base of the transistor comprises a doped small molecule organic material that forms a junction with the collector. An emitter comprises a small molecule organic material that forms a junction with the base. A first electrode is coupled to the collector, a second electrode is coupled to the base, and a third electrode is coupled to the emitter, wherein the transistor is bipolar. The transistor's collector-base junction and emitter-base junction may each be, for example, planar junctions or bulk junctions. Various materials may be utilized for the collector, base, and emitter regions; in one embodiment, the materials are comprised essentially of stable planar stacking molecules. The organic material used for collector, base, and emitter regions may be doped with n-type or p-type dopants.

### BRIEF DESCRIPTION OF THE DRAWINGS

FIG. 1 illustrates a schematic diagram of an organic heterojunction bipolar transistor in accordance with an embodiment of the invention.

FIG. 2 is an illustration of an integrated shadow mask in accordance with an embodiment of the invention.

FIG. 3 is a graphical representation 300 of the mobility of 3,4,9,10 perylenetetracarboxylic dianhyrdride (PTCDA) thin films as a function of deposition rate in ultrahigh vacuum.

FIG. 4 is a pair of photomicrographs illustrating the variation in crystal texture and hole mobility in pentacene thin films grown in kinetic and equilibrium growth regimes.

FIG. 5 is a schematic diagram of an organic heterojunction bipolar transistor in accordance with an embodiment of the invention.

### DETAILED DESCRIPTION

Disclosed herein is structure for a very high bandwidth, high gain heterojunction bipolar, small molecular weight thin film transistor. This structure, with its very high bandwidth and high gain, results from high p- and n-type doping of organic materials. The highly p- and n-type doped molecular organic materials results in high conductivity in comparison to the normally undoped (and hence highly resistive) molecular organic materials. See, e.g., M. Pfeiffer et al., “A low drive voltage, transparent, metal-free n-i-p electrophosphorescent light emitting diode” Organic Electron., vol. accepted, 2003; M. Pfeiffer et al., “Electrophosphorescent p-i-n organic light emitting devices for very high efficiency flat panel displays,” Adv. Mat., vol. 14, pp. 1633, 2002; M. Pfeiffer et al., “Controlled doping of phthalocyanine layers by cosublimation with acceptor molecules: A systematic Seebeck and conductivity study,” Appl. Phys. Lett., vol. 73, pp. 3202, 1998; W. Gao and A. Kahn, “Controlled p-type doping of an organic molecular semiconductor,” Appl. Phys. Lett., vol. 79, pp. 4040, 2001; J. Blochwitz et al., “Low voltage organic light emitting diodes featuring doped phthalocyanine as hole transport material,” Appl. Phys. Lett., vol. 73, pp. 729, 1998; and G. Parthasarathy et al. “Lithium Doping of Semiconducting Organic Charge Transport Materials,” J. Appl. Phys., vol. 89, pp. 4986, 2001.

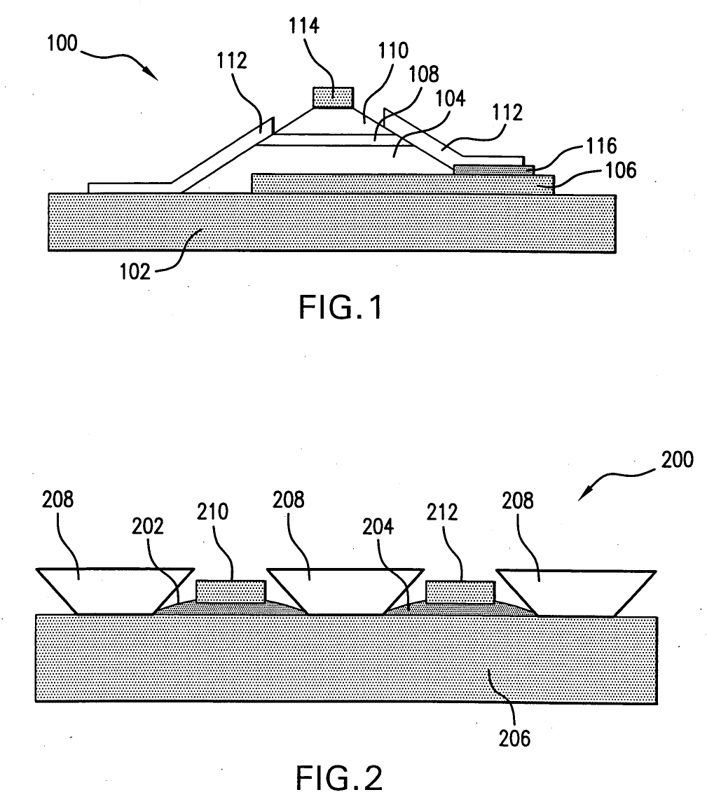

Referring now in detail to the drawings, there is illustrated in FIG. 1 illustrates a schematic diagram of an organic heterojunction bipolar transistor 100 in accordance with an embodiment of the invention. Transistor 100 includes a base region 108 that forms a heterojunction with both a collector region 104 and an emitter region 110. Although FIG. 1 illustrates a stacked configuration with collector region 104 on bottom, base region 108 in the middle, and emitter region 110 on top, other configurations may be used. For example, the order of the stack may be reversed, such that collector region 104 is on top. Or, the regions may be arranged side-by-side in a non stacked configuration. Or, there may be partial overlap of organic regions. The basic structure generally has a base region 108 that forms a heterojunction with both a collector region 104 and an emitter region 110, without being limited to the particular geometry illustrated in FIG. 1. The junction between the base and emitter, as well as the junction between the base and the collector, may be any suitable type of junction, for example a planar junction or a bulk junction.

The particular embodiment of FIG. 1 may be fabricated as follows. A collector region 104 may be deposited onto the surface of a metal collector contact 106. A base region 108 may be deposited onto the surface of the collector region 104. An emitter region 110 may be deposited on the base region 108. A metal base contact 112 and a metal emitter contact 114 are deposited to both the base region 108 and the emitter region 110, respectively. An insulator 116 may be interposed between the metal contact 106 and the metal base contact 112.

Substrate 102 may be any suitable substrate that provides desired structural properties. Substrate 102 may be flexible or rigid. Substrate 102 may be transparent, translucent, or opaque. Plastic and glass are examples of preferred rigid substrate materials. Plastic and metal foils are examples of preferred flexible substrate materials. Substrate 102 may be a semiconductor material in order to facilitate the fabrication of circuitry. For example, substrate 102 may be a silicon wafer upon which circuits are fabricated, capable of controlling OLEDs subsequently deposited on the substrate. Other substrates may be used. The material and thickness of substrate 102 may be chosen to obtain desired structural and optical properties.

A collector region 104 may be deposited onto the surface of a metal collector contact 106. The metal collector contact 106 may be any suitable metal and is preferably gold. The metal collector contact 106 may be prepatterned on a substrate 102 surface. The collector region 104 may be deposited in a vacuum or by organic vapor jet printing (OVJP). Other methods to deposit the collector region 104 may be used without departing from the scope of the invention. In one exemplary embodiment, the organic heterojunction bipolar transistor 100 is constructed as an n-p-n transistor. In that exemplary embodiment, the collector region 104 consists essentially of highly stable copper phthalocyanine (CuPc). CuPc has an energy gap of 1.7 eV. See S. R. Forrest, “Ultrathin Organic Films Grown by Organic Molecular Beam Deposition and Related Techniques,” Chem. Rev., vol. 97, pp. 1793, 1997. CuPc may act as an n-type material for a collector when nominally undoped. Preferably, CuPc may be lightly doped with an n-type dopant such as Li, which may be co-deposited with the CuPc during deposition. See G. Parthasarathy et al., “Lithium Doping of Semiconducting Organic Charge Transport Materials,” J. Appl. Phys., vol. 89, pp. 4986, 2001. Generally, the conductivity of a “p-type” layer is due mostly to hole conduction, and the conductivity of an “n-type” layer is due mostly to electron conductivity. p- or n-type conductivity may be acheived by doping with suitable dopants, or, for many organic materials, p- or n-type conductivity may be a property of the undoped material.

For large geometry (e.g., gate contact on the order of 10 μm) transistors, confinement of the organic deposition to the contact region can be done by deposition through a shadow mask. To achieve very high bandwidths, however, the base-collector capacitance (C_{BC}) is preferably minimized, through more aggressive control of the base dimensions.

A base region 108 may be deposited onto the surface of the collector region 104. In one embodiment, the base region 108 may be 0.5-10 nm thick. The organic material of the base region 108 may be CuPc. In the exemplary embodiment of the n-p-n transistor disclosed herein, the CuPc may be heavily p-type doped with a molecular organic compound, such as, for example, F₄-TCNQ. With these and similar materials, “heavily” doped may be at a doping concentration of 0.1 mol % or greater, and preferably 1 mol % or greater. These doping concentrations are expected to cause a decrease in resistivity. Such thin (0.5-10 nm thick) and continuous layers are routinely achieved using vacuum and vapor deposition processes. See S. R. Forrest, “Ultrathin Organic Films Grown by Organic Molecular Beam Deposition and Related Techniques,” Chem. Rev., vol. 97, pp. 1793, 1997. Preferably, the base has an in-plane resistivity of 100 kΩ-cm or less, and more preferably 1 kΩ or less. It is expected that these low resistivities will result in a transistor having desirable properties.

Next, an emitter region 110 may be deposited on the base region 108. In the exemplary embodiment of the n-p-n transistor disclosed herein, emitter region 110 is an n-type layer. Preferably, the host material is a wide-energy-gap material, such as, for example, 3,4,9,10 perylenetetracarboxylic dianhyrdride (PTCDA) or bis (1,2,5 thiadiazolo)-p-quinobis (1,3-dithiole) (BTQBT). The material may be either undoped (for materials that are n-type when undoped) or lightly doped with an n-type dopant such as Li. See J. Xue and S. R. Forrest, “Organic thin-film transistors based on bis (1,2,5 thiadiazolo)-p-quinobis (1,3-dithiole),” Appl. Phys. Lett., vol. 79, pp. 3714, 2001.

In the case of PTCDA, a planar stacking molecular material, hole mobilities of 1 cm²/V-s have been realized in vacuum deposited films on glass. See S. R. Forrest, M. L. Kaplan, and P. H. Schmidt, “Organic-on-inorganic semiconductor contact barrier diodes.II. Dependence on Organic Film and Metal Contact Properties,” J. Appl. Phys., vol. 56, pp. 543, 1984. Accordingly, PTCDA is a preferred material for high bandwidth organic bipolar transistor applications.

Next, metal base contact 112 and metal emitter contact 114 are deposited to both the base region 108 and the emitter region 110, respectively. Contacts 112, 114 may be deposited by vacuum deposition or some other method without departing from the scope of the invention. In a preferred embodiment as illustrated in FIG. 1, using deposition at an angle, the metal of contact 112 may make contact around substantially the entire periphery of the base region 108. The metal composition of contact 112 may be chosen such that it does not lead to ohmic injection into the n-type collector region 104 and/or emitter region 110. An insulator 116 is preferably interposed between the metal collector contact 106 and the metal base contact 112. The insulator 116 may be SiOₓ or SiNₓ, for example.

Using different materials, a p-n-p transistor may be constructed. An example of materials for a p-type collector region 104 and/or emitter region 110 is CuPc doped with tetrafluoro-tetracyano-quinodimethane (F₄-TCNQ). Undoped (or lightly doped) N,N′-diphenyl-N-N′-di(1-naphthyl)-benzidine (NPD) is another example of a suitable p-type layer, particularly for a situation where an undoped p-type layer is desired, such as an undoped emitter. An example of materials that may be used to create an n-type base is CuPc doped with lithium, preferably heavily doped. Material combinations in addition to those disclosed herein may be used, for both n-p-n and p-n-p transistors.

In the embodiment of FIG. 1, the total thickness of the organic layers 104, 108, and 110 in the transistor 100 is ˜100 nm. By choosing organic materials such that emitter material energy gap is larger than that of base or collector material energy gaps, the advantage of high current gain (β˜100) associated with Si-based heterojunction bipolar transistors may be realized.

Geometries other than the one specifically illustrated in FIG. 1 may be used, so long as there is a base coupled to both a collector and emitter. For example, other embodiments include an embodiment where the organic layers are stacked vertically as in FIG. 1, but in the opposite order, and an embodiment where the collector, base and emitter are laterally displaced instead of and/or in addition to vertically displaced.

Transistor bandwidth may be limited by the base transit time. By stacking the collector region 104, base region 108, and emitter region 110 in a “growth direction,” perpendicular to the substrate 102 plane, a geometry may be acheived with a base transit distance that is much smaller than in other geometries, such as devices having a base, collector, and emitter laterally displaced from each other. With a base thickness of <10 nm, transistor bandwidths of 10-100 MHz may be realizable.

It is believed that certain planar stacking molecules, such as CuPc, may be used to acheive high carrier mobilities (>2 cm²/V-s) in the stacked transistor geometry. The use of such planar stacking molecules is preferred.

An estimate of the bandwidth of the transistor may be calculated. Assuming a base lateral dimension of 10 μm (achieved by deposition through a shadow mask), and 1 μm as achieved using direct printing methods such as OVJP or by cold welding printing techniques. See C. Kim et al., “Micropatterning of Organic Electronic Devices by Cold-Welding,” Science, vol. 288, pp. 831, 2000; C. Kim and S. R. Forrest, “Fabrication of organic light-emitting devices by low pressure cold welding,” Adv. Mat., vol. 15, 2003; and C. Kim et al., “Nanolithography based on patterned metal transfer and its application to organic electronic devices,” Appl. Phys. Lett., vol. 80, pp. 4051, 2002.

In the small signal limit, the cutoff frequency is given by:

$${f}_{T} = {\{ 2 π [ \frac{{kTC}_{BE}}{{qI}_{c}} + \frac{{d}^{3}}{2 {L}_{B}^{2} {v}_{S}} + \frac{{W}_{c} - d}{2 {v}_{S}} ] \}}^{- 1} \qquad Eqn . 1$$

See S. M. Sze, Physics of Semiconductor Devices, 2ed. New York: John Wiley, 1981, page 159.

In Eqn. 1, above, the first term is the emitter charging time, with I_{C} equal to the collector current and C_{BE} the base-emitter junction capacitance. The second term is due to carrier diffusion across the base of width d, assuming a diffusion length of LB and a velocity, v_{S}, The third term is due to carrier drift across the collector depletion width, W_{C}. Now, under large collector currents, we can neglect the first term. Assuming typical values of v_{S}=10⁴ cm/s, d=5 nm, W_{C}=20 nm, and L_{B}=1 nm, then we obtain f_{T}=250 MHz. However, a more significant limitation arises from the base resistance, r_{B}.

The maximum oscillation frequency of the transistor is given by:
fₘₐₓ≅\sqrt{f_{T}/2πr_{B}C_{BC}} Eqn. 2

Given an n-type doping density of the base of ˜2×10¹⁹ cm⁻³, and a carrier mobility of 2 cm²/V-s, a base resistance of about 5 Ω may be calculated (assuming ohmic contact is made to all four sides of the base layer), resulting in fₘₐₓ≈100 MHz.

Note that these bandwidths refer to the small signal characteristics of the bipolar transistors. In this mode of operation, the transistors can be used in such linear circuit applications as macroelectronic sensor arrays. However, in smart display backplanes, for example, the transistors may also be used as switches in the large signal domain. In this operating regime, the bandwidth is expected to be lower than 100 MHz.

To capture the advantages of organic devices distributed across large substrates, there is preferably also a very low cost, precise means for patterning and processing the devices. While deposition through small apertures in shadow masks provides one such approach, even small feature sizes (<10 μm) may be extremely difficult to obtain and may not be achievable over large substrate areas (>50 cm). Hence, in the long term, the goals for achieving high performance macroelectronic circuits are not attainable and other patterning methods may have to be devised.

FIG. 2 is an illustration of an integrated shadow mask (ISM) 200 in accordance with an embodiment of the invention. Here, deposition of organic deposit(s) 202, 204 may be accomplished while the position of the substrate 206 in relation to the evaporation source (not shown) is varied, hence allowing the organic deposit(s) 202, 204 to extend beneath an undercut mask 208, which stands approximately 1 μm above the substrate 206 surface. Next, metal contacts 210, 212 may be deposited without substrate motion, resulting in highly confined metal deposits 210, 212 relative to the predeposited organic pattern. This technique may be capable of submicron pattern resolutions similar to that achieved using conventional photolithography.

Unfortunately, photolithographic processes are difficult to control over large and flexible substrate areas. Hence, direct printing technologies, such as OVJP, may be employed. See M. Shtein et al., “Micropatterning of organic thin films for device applications using organic vapor phase deposition,” J. Appl. Phys, vol. 93, pp. 4005, 2003; U.S. patent application No. 422,269 to Shtein et al, which is incorporated by reference in its entirety.

The organic transistors as described herein, may result in a breakthrough in the performance of organic thin film transistors and circuits, because they control the flow of charge perpendicular to the substrate plane, that is in the film growth direction organic transistors having small lateral dimensions, on the order of 10 μm may be achieved. This is in contrast to current organic field effect thin film transistors, see M. Shtein et al. “Effects of film morphology and gate dielectric surface preparation on the electrical characteristics of organic vapor phase deposited pentacene thin-film transistors,” Appl. Phys. Lett., vol. 81, pp. 268, 2002; D. J. Gundlach et al. “Pentacene organic thin film transistors-molecular ordering and mobility,” IEEE Electron. Dev. Lett., vol. 18, pp. 87,1997; Y. Y. Lin et al. “Pentacene Thin Film Transistors with Improved Subthreshold Slope,” presented at Mat. Res. Soc. Spring Mtg., San Francisco, Calif., 1997; Y. Y. Lin et al. “High-mobility pentacene-based organic thin film transistors,” presented at 55th Ann. Dev. Res. Conf, Ft. Collins, Colo., 1997, which occupy considerable space in the lateral (in-plane) direction, and hence inevitably have larger dimensions (10 μm vs. 10 nm). See M. Shtein et al., “Effects of film morphology and gate dielectric surface preparation on the electrical characteristics of organic vapor phase deposited pentacene thin-film transistors,” Appl. Phys. Lett., vol. 81, pp. 268, 2002; D. J. Gundlach et al., “Pentacene organic thin film transistors-molecular ordering and mobility,” IEEE Electron. Dev. Lett., vol. 18, pp. 87, 1997; Y.-Y. Lin et al., “Pentacene Thin Film Transistors with Improved Subthreshold Slope,” presented at Mat. Res. Soc. Spring Mtg., San Francisco, Calif., 1997; Y. Y. et al., “High-mobility pentacene-based organic thin film transistors,” presented at 55th Ann. Dev. Res. Conf., Ft. Collins, Colo., 1997.

All other aspects of the devices being equal, this may result in a 1000 fold increase in transistor bandwidth. However, given the ability to achieve ordered growth in organic films consisting of planar stacking molecules such as PTCDA, higher charge mobilities may be expected in these vertical devices, in contrast to conventional, lateral thin film transistor. See S. R. Forrest, “Ultrathin Organic Films Grown by Organic Molecular Beam Deposition and Related Techniques,” Chem. Rev., vol. 97, pp. 1793, 1997.

By doping of emitter and base layers with conductive dopants such as L₁ and F₄-TCNQ, the bandwidth of the devices may increase yet further, allowing for fₘₐₓ˜100 MHz. In the case of PTCDA purified by multiple thermal gradient sublimation cycles, hole mobility varying between μₚ=0.01 and 1 cm² V-s in thin films grown under ultrahigh vacuum growth conditions have consistently been found.

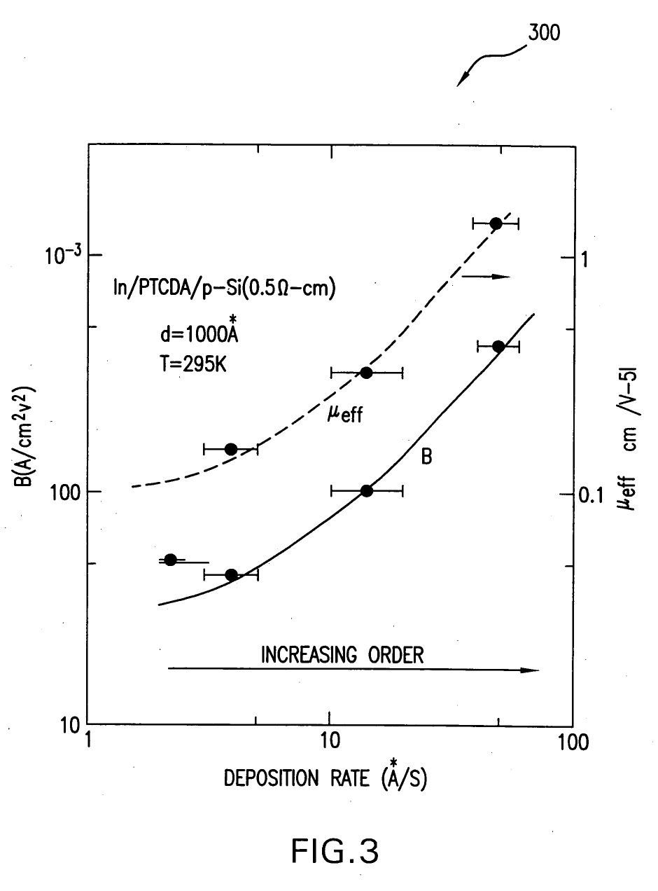

FIG. 3 is a graphical representation 300 of the mobility of PTCDA thin films as a function of deposition rate in ultrahigh vacuum. As expected, and as illustrated in FIG. 3, higher mobilities may be achieved under growth conditions leading to a higher degree of stacking order. See S. R. Forrest et al., “Organic-on-inorganic semiconductor contact barrier diodes.II. Dependence on Organic Film and Metal Contact Properties,” J. Appl. Phys., vol. 56, pp. 543, 1984.

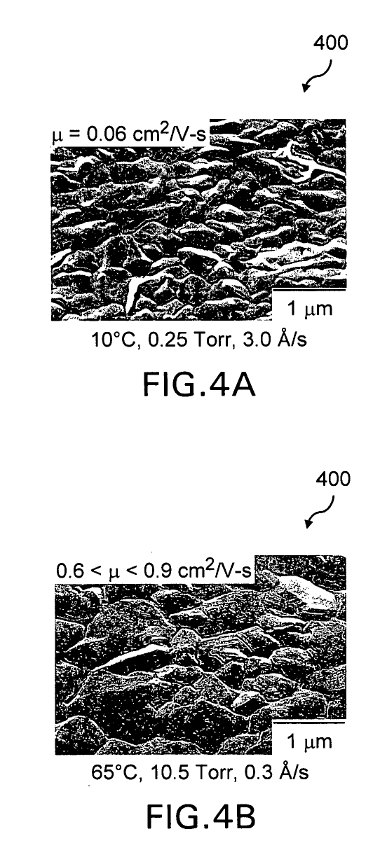

FIG. 4 is a pair of photomicrographs 400 illustrating the variation in crystal texture and hole mobility in pentacene thin films grown in kinetic and equilibrium growth regimes. Organic vapor phase deposition (OVPD) has been demonstrated to grow polycrystalline thin films of pentacene for thin film transistors. The use of OVPD to control crystallite size in a pentacene channel by varying the growth conditions from the equilibrium to the kinetic regimes is illustrated in the photomicrograph of FIG. 4. See also M. Shtein et al., “Effects of film morphology and gate dielectric surface preparation on the electrical characteristics of organic vapor phase deposited pentacene thin-film transistors,” Appl. Phys. Lett., vol. 8 1, pp. 268, 2002.

The field effect mobilities obtained using OVPD are ˜1.5 cm²/V-s; typical of the best pentacene thin film transistors deposited in vacuum. See A. Dodabalapur et al., “Organic Field-Effect Bipolar Transistors,” Appl. Phys. Lett., vol. 68, pp. 1108, 1996; L.-B. Lin et al., “Hole injection and transport in tris-(8 hydroxyquinolinato) aluminum,” Appl. Phys. Lett., vol. 70, pp. 2052, 1997. These mobilities are typically two orders of magnitude higher than the best solution processed polymer based transistors. See G. H. Gelinck et al., “High-performance all-polymer integrated circuits,” Appl. Phys. Lett., vol. 77, pp. 1487, 2000.

Enhancing the conductivity of the as-grown layers, can further reduce the charge transport time. One method, discussed above, may be to use kinetic growth to increase the range of ordering of these naturally polycrystalline materials. A second enhancement may be made possible by the recent demonstration in several groups of successful high p- and n-type doping leading to high conductivity of the normally undoped (and hence highly resistive) molecular organic materials. See, e.g., M. Pfeiffer et al., “A low drive voltage, tfansparent, metal-free n-1-p electrophosphorescent light emitting diode”,,” Organic Electron., vol. 4, p. 21, 2003; M. Pfeiffer et al., “Electrophosphorescent p-1-n organic light emitting devices for very high efficiency flat panel displays,” Adv. Mat., vol. 14, pp. 1633, 2002; M. Pfeiffer et al., “Controlled doping of phthalocyanine layers by cosublimation with acceptor molecules: A systematic Seebeck and conductivity study,” Appl. Phys. Lett., vol. 73, pp. 3202, 1998; W. Gao and A. Kahn, “Controlled p-type doping of an organic molecular semiconductor,” Appl. Phys. Lett., vol. 79, pp. 4040, 2001; J. Blochwitz et al., “Low voltage organic light emitting diodes featuring doped plithalocyanine as hole transport material,” Appl. Phys. Lett., vol. 73, pp. 729, 1998; G. Parthasarathy et al., “Lithium Doping of Semiconducting Organic Charge Transport Materials,” J. Appl. Phys., vol. 89, pp. 4986,2001.

One patterning method for possible use on organic heterojunction bipolar transistors, and already successfully applied to organic emissive displays, is the integrated shadow mask (ISM) consisting of an undercut polymer ridge photolithographically patterned on the substrate surface prior to organic film deposition. FIG. 6 illustrates an organic heterojunction bipolar transistor, such as that described in connection with the illustration of FIG. 1, which may be manufactured using an ISM process.

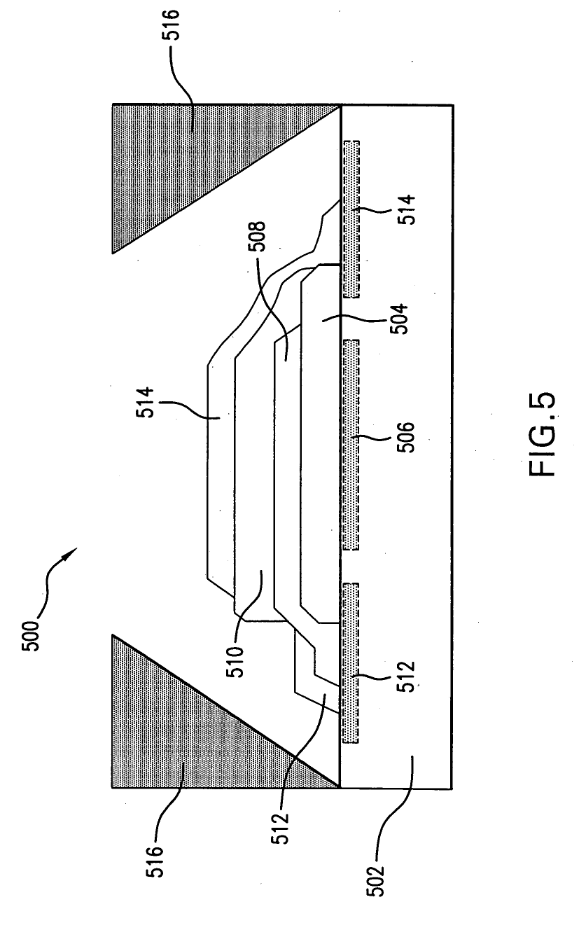

FIG. 5 is a schematic diagram of an organic heterojunction bipolar transistor 500 in accordance with an embodiment of the invention that may use a pre-fabricated integrated shadow mask to enable patterning of organic and electrode layers without the use of lithography or similar processes subsequent to organic deposition, that may damage the organic layers. Substrate 502 may be any suitable substrate that provides desired structural properties. A collector region 504 may be deposited onto the surface of a metal collector contact 506. A base region 508 may be deposited onto the surface of the collector region 504. An emitter region 510 may be deposited on the base region 508. A metal base contact 512 and a metal emitter contact 514 are deposited to both the base region 508 and the emitter region 510, respectively. An integrated shadow mask 516 (similar to 208, FIG. 2). Details of a method for micropatterning using an integrated shadow mask may be found in U.S. Pat. No. 5,953,587, incorporated herein by reference in its entirety.

While the organics can be deposited using OVJP, other methods may be more suitable for patterning the contacts. For example, contact attachment may be achieved by using the direct printing technique of cold welding followed by lift-off. In this method, the metal contact may be first deposited onto a soft “stamp” premolded into the pattern desired for the contact. See C. Kim et al., “Micropatterning of Organic Electronic Devices by Cold-Welding,” Science, vol. 288, pp. 831, 2000; C. Kim and S. R. Forrest, “Fabrication of organic light-emitting devices by low pressure cold welding,” Adv. Mat., vol. 15, 2003; C. Kim et al., “Nanolithography based on patterned metal transfer and its application to organic electronic devices,” Appl. Phys. Lett., vol. 80,pp. 4051,2002. This stamp may be then pressed at a surprisingly low pressure (1 atm) onto the substrate surface, leaving the metal from the stamp behind on the substrate. This process has nanometer scale resolution, and results in devices whose characteristics are comparable to those attained using conventional vacuum deposition methods. By placing the stamp surface onto a “roller,” direct and continuous, very high resolution printing of the contacts and organic patterns by a combination of stamping and OVJP may be achieved.

An alternative to applying the contacts after OVJP printing may be to pre-pattern the contact pads and circuit interconnect patterns onto the substrate before the printing process.

Unless otherwise specified, any of the layers of the various embodiments may be deposited by any suitable method. For the organic layers, preferred methods include thermal evaporation, ink-jet, such as described in U.S. Pat. Nos. 6,013,982 and 6,087,196, which are incorporated herein by reference in their entireties, organic vapor phase deposition, such as described in U.S. Pat. No. 6,337,102 to Forrest et al., which is incorporated herein by reference in its entirety, and deposition by organic vapor jet printing, such as described in U.S. patent application Ser. No. 10/233,470, which is incorporated herein by reference in its entirety.

Other suitable deposition methods include spin coating and other solution based processes. Solution based processes are preferably carried out in nitrogen or an inert atmosphere. For the other layers, preferred methods include thermal evaporation. Preferred patterning methods include deposition through a mask, cold welding such as described in U.S. Pat. Nos. 6,294,398 and 6,468,819, which are incorporated herein by reference in their entireties, and patterning associated with some of the deposition methods such as ink-jet and OVJP. Other methods may also be used. The materials to be deposited may be modified to make them compatible with a particular deposition method. For example, substituents such as alkyl and aryl groups, branched or unbranched, and preferably containing at least 3 carbons, may be used in small molecules to enhance their ability to undergo solution processing. Substituents having 20 carbons or more may be used, and 3-20 carbons is a preferred range. Materials with asymmetric structures may have better solution processibility than those having symmetric structures, because asymmetric materials may have a lower tendency to recrystallize. Dendrimer substituents may be used to enhance the ability of small molecules to undergo solution processing.

Devices fabricated in accordance with embodiments of the invention may be incorporated into a wide variety of consumer products, including flat panel displays, computer monitors, televisions, billboards, lights for interior or exterior illumination and/or signaling, heads up displays, fully transparent displays, flexible displays, laser printers, telephones, cell phones, personal digital assistants (PDAs), laptop computers, digital cameras, camcorders, viewfinders, micro-displays, vehicles, a large area wall, theater or stadium screen, or a sign. Various control mechanisms may be used to control devices fabricated in accordance with the present invention, including passive matrix and active matrix. Many of the devices are intended for use in a temperature range comfortable to humans, such as 18-30 C, and more preferably at room temperature (20-25 C).

As used herein, “solution processible” means capable of being dissolved, dispersed, or transported in and/or deposited from a liquid medium, either in solution or suspension form. Solution processible includes solution casting, such as in the deposition of a polymeric material onto a surface.

If a small molecular weight organic thin film such as pentacene is employed, it is preferably deposited by vacuum or other vapor deposition process, and if it is a polymer, it is preferably solution cast. However, the highest field-effect mobilities (by far) have been obtained using small molecular weight materials. See, e.g., S. R. Forrest, “Ultrathin Organic Films Grown by Organic Molecular Beam Deposition and Related Techniques,” Chem. Rev., vol. 97, pp. 1793, 1997. Accordingly, such a materials system is used for exemplary purposes herein.

Typical field effect mobilities for pentacene channels are ˜1 cm²/V-s, and are limited by transport across polycrystalline grain boundaries that develop in the channel. In this case, the highest bandwidth circuits reported using pentacene thin film transistors is ˜10-50 kHz. While decreasing the gate length also may decrease the number of grain boundaries that are transited by the charge from source to drain, reducing the source—drain spacing unfortunately also introduces “short channel effects” that degrade performance such as transistor threshold voltage and on/off current ratio. Hence, while it may be possible to decrease the gate length to micron or even sub-micron dimensions, little or no advantage in FET performance is realized. This has been most clearly demonstrated in a very short channel polymer FET grown in a “V” groove. See N. Stutzmann, R. H. Friend, and H. Sirringhaus, “Self-aligned, vertical-channel, polymer field-effect transistors,” Science, vol. 299, pp. 1881, 2003. While FET action was observed, short channel effects may ultimately limit the characteristics.

Hence, a fundamental limit to conventional, small molecule organic thin film transistor bandwidths is 100 kHz. While mobilities can be improved somewhat by eliminating crystalline grain boundaries in the channel using extraordinary measures such as epitaxial growth on substrates such as NaCl or KCl, See S. R. Forrest, “Ultrathin Organic Films Grown by Organic Molecular Beam Deposition and Related Techniques,” Chem. Rev., vol. 97, pp. 1793, 1997, the ultimate limit to charge mobility is <5 cm² N-s due to intermolecular thermal motion characteristic of van der Waals bonded solids such as small molecules. The limits to non-aligned polymers are even more severe—probably room temperature mobilities no larger than 10⁻² cm² V-s are feasible. Prealignment of polymer chains onto the substrate by surface preparations such as those employed in liquid crystal displays may yield a mobility increase by a factor of ten.

Should higher transistor bandwidths be achieved, the advantages of using organics to other Si-based technologies are manifold. For example, very low cost processing at low temperatures on plastic substrates can be readily realized using organic thin films. Furthermore, very large, or even continuous substrate fabrics can be used in conjunction with “direct printing” of the organic transistor circuits using such techniques such as inkjet or organic vapor jet printing.

While certain embodiments are illustrated herein, it is understood that different geometries may be used without departing from the scope of the present invention.

While the present invention is described with respect to particular examples and preferred embodiments, it is understood that the present invention is not limited to these examples and embodiments. The present invention as claimed therefore includes variations from the particular examples and preferred embodiments described herein, as will be apparent to one of skill in the art.

1. A transistor, comprising:
a collector comprising a small molecule organic material;
a base comprising a doped small molecule organic material that forms a junction with the collector;
an emitter comprising a small molecule organic material that forms a junction with the base;
a first electrode coupled to the collector;
a second electrode coupled to the base;
a third electrode coupled to the emitter;
wherein the transistor is bipolar.

2. The transistor of claim 1, wherein the collector-base junction is one of a planar junction and a bulk junction.

3. The transistor of claim 1, wherein the emitter-base junction is one of a planar junction and a bulk junction.

4. The transistor of claim 1, wherein the base comprises planar stacking molecules.

5. The transistor of claim 1, wherein the collector is an n-type layer.

6. The transistor of claim 5, wherein the collector includes an n-type dopant.

7. The transistor of claim 6, wherein the material of the collector comprises CuPc doped with lithium.

8. The transistor of claim 1, wherein the base is a p-type layer that includes a p-type dopant.

9. The transistor of claim 8, wherein the material of the base further comprises CuPc doped with F₄-TCNQ.

10. The transistor of claim 1, wherein the emitter is an n-type layer.

11. The transistor of claim 10, wherein the material of the emitter further comprises a material selected from the group consisting of undoped PTCDA and undoped BTQBT.

12. The transistor of claim 10, wherein the emitter includes an n-type dopant.

13. The transistor of claim 12, wherein the material of the collector is selected from the group consisting of further comprises a material selected from the group consisting of: PTCDA doped with Li, and BTQBT doped with Li.

14. The transistor of claim 1, wherein the collector is a p-type layer.

15. The transistor of claim 14, wherein the collector includes a p-type dopant.

16. The transistor of claim 15, wherein the material of the collector comprises CuPc doped with F₄-TCNQ.

17. The transistor of claim 1, wherein the base is an n-type layer that includes an n-type dopant.

18. The transistor of claim 17, wherein the material of the base further comprises CuPc doped with Li.

19. The transistor of claim 1, wherein the emitter is a p-type layer.

20. The transistor of claim 19, wherein the material of the emitter further comprises undoped NPD.

21. The transistor of claim 19, wherein the emitter includes a p-type dopant.

22. The transistor of claim 21, wherein the material of the emitter comprises CuPc doped with F₄-TCNQ.

23. The transistor of claim 1, wherein the collector, base, and emitter materials are chosen such that an emitter material energy gap is larger than that of base and collector energy gaps.

24. The transistor of claim 1, wherein the collector, the base, and the emitter are vertically stacked.

25. The transistor of claim 1, wherein the collector, the base, and the emitter are laterally displaced from each other.

26. The transistor of claim 1, wherein the transistor has a bandwidth greater than 10 MHz.

27. The transistor of claim 1, wherein the transistor has a current gain of at least 100.

28. The transistor of claim 1, wherein the combined thickness of the emitter, the base, and the collector is less than about 100 nm.

29. The transistor of claim 1, wherein the base has an in-plane resistivity less than about 100 kΩ-cm.

30. The transistor of claim 1, wherein the base has an in-plane resistivity less than about 1 kΩ-cm.

31. The transistor of claim 1, wherein the material of the base is an n-type conductor and the materials of the emitter and collector are p-type conductors.

32. The transistor of claim 1, wherein the material of the base is an p-type conductor and the materials of the emitter and collector are n-type conductors.
